(19) United States
(12) Patent Application Publication
(10) Pub. No.: US 2005/0223973 A1
(43) Pub. Date: Oct. 13, 2005

(54) EUV lithography system and chuck for releasing reticle in a vacuum isolated environment

(75) Inventors: Siegfried Schwarzl, Neubiberg (DE); Stefan Wurm, Austin, TX (US)

Correspondence Address: MORRISON & FOERSTER LLP, 1650 TYSONS BOULEVARD, SUITE 300, MCLEAN, VA, 22102, US

(73) Assignee: Infineon Technologies AG, Munchen (DE)

(21) Appl. No.: 10/812,411

(22) Filed: Mar. 30, 2004

(51) Int. Cl. G03F 9/00; C23C 16/00

(52) U.S. Cl. 118/58; 430/5; 361/234

(57) ABSTRACT

An EUV lithography system is disclosed. The EUV lithography system comprises a mask chamber having one or more vacuum valves for isolating the mask chamber from the rest of the lithography system, a gas supply line adapted to provide an inert gas to the mask chamber to dechuck the reticle, and a vacuum pump adapted to re-evacuate the mask chamber after the reticle has been released. The one or more vacuum valves are closed to isolate the mask chamber from the rest of the EUV lithography system before venting the mask chamber with an inert gas, such as nitrogen, to release the reticle from the chuck. The chuck in the EUV system may further comprise a contact surface for holding a back surface of the reticle to the chuck, and a plurality of openings in the chuck, each opening having a first end and a second end, the first end of each opening being coupled to the gas supply line, and the second end of each opening being coupled to the contact surface of the chuck. The gas supply line provides the inert gas to the contact surface of the chuck and the back surface of the reticle via the plurality of openings in the chuck to release the reticle from the chuck. After the reticle has been released, the mask chamber is re-evacuated again before wafer exposure is started.

### FIELD OF THE INVENTION

The present invention relates generally to a lithography system. More specifically, the present invention relates to a system and method for vacuum isolation of a mask chamber in an Extreme Ultraviolet (EUV) lithography system for releasing a reticle from a chuck.

### BACKGROUND OF THE INVENTION

Lithography systems are used in the manufacture of integrated circuits and related devices. Such systems are well known in the art and have proven effective in forming and reproducing the very fine geometries of a circuit image on a silicon wafer.

Extreme Ultraviolet (EUV) lithography systems use wavelenghts of about 10 nm to 15 nm and are used for lithography structures with dimensions smaller than 50 nm. EUV lithography systems, as well as other next generation technologies, generally must operate in a high vacuum environment instead of operating under a controlled environment at 1 atmosphere as was common of prior art non-EUV systems.

FIG. 1 illustrates a conventional EUV lithography system 100. The EUV lithography system comprises two (2) chambers: the illuminator chamber 102 that houses the laser-produced plasma source 50 and the main chamber 103 that houses the mask or reticle stage 104, the projection optics 106, and a wafer stage 108.

A mask or reticle chuck mounted on the mask stage 104 is used to securely hold the reticle in an EUV lithography system during the lithography process. Because the EUV lithography process must take place in a vacuum, vacuum chucks cannot be used. Similarly, clamping chucks, which hold the reticle at the edges, are also undesirable to use mainly due to particles generated at the area where the reticle is clamped. Thus, electrostatic chucks will be typically used in EUV lithography systems. Because the reticle moves quickly during a reticle scan and because the reticle must be stable and even during the scan, electrostatic chucks exert an extremely high pressure on the reticle, around 15 kPa, to secure the reticle during processing.

As a result, the throughput associated with current EUV lithography systems is limited due in part to the time required to release the reticle from the reticle chuck for reticle changes. Electrostatic chucks secure the reticle using electrical polarization. When the polarization is reversed, the reticle is released from the chuck. In an atmoshperic environment, this process works well. However, in a vacuum system, the depolarization process can take longer thereby increasing the time required for the reticle to be released by the chuck.

Therefore, what is needed is a system and method for enabling reticles to be quickly released from a reticle chuck in a vacuum environment.

### SUMMARY OF THE INVENTION

According to the present invention, these objects are achieved by a system and method as defined in the claims. The dependent claims define advantageous and preferred embodiments of the present invention.

In one embodiment of the invention, an EUV lithography system for processing a substrate comprises a mask chamber having one or more vacuum valves for isolating the mask chamber from the rest of the lithography system, a gas supply line adapted to provide an inert gas to the mask chamber, and a vacuum pump adapted to re-evacuate the mask chamber. In one embodiment of the present invention, the one or more vacuum valves are closed to isolate the mask chamber from the rest of the EUV lithography system before venting the mask chamber by the vacuum pump. After the mask chamber has been isolated, the gas supply line proivdes an inert gas, such as nitrogen, to the mask chamber to release the reticle from the chuck.

In another embodiment of the invention, the EUV lithography system further comprises a chuck mounted in the mask chamber for holding the reticle. The chuck further comprises a contact surface for holding a back surface of the reticle to the chuck, and a plurality of openings in the chuck, each opening having a first end and a second end, the first end of each opening being coupled to the gas supply line, and the second end of each opening being coupled to the contact surface of the chuck. The gas supply line provides the inert gas to the contact surface of the chuck and the back surface of the reticle via the plurality of openings in the chuck for releasing the reticle from the chuck.

In another embodiment of the present invention, a method for providing a vacuum isolated environment in an EUV lithography system for releasing a reticle from a chuck comprises the steps of: providing a mask chamber having one or more vacuum valves for isolating the mask chamber from the lithography system, closing the one or more vacuum valves to isolate the mask chamber from the rest of the lithogaphy system, venting the mask chamber by providing an inert gas, such as nitrogen, to the mask chamber after the mask chamber has been isolated to release the reticle from the chuck.

In another embodiment of the present invention for providing a vacuum isolated environment in an EUV lithography system for dechucking a reticle, the method further comprises the steps of providing a chuck having a contact surface for holding a back surface of the reticle to the chuck, and providing a plurality of openings in the chuck, each opening having a first end and a second end, the first end of each opening being coupled to the gas supply line, and the second end of each opening being coupled to the contact surface of the chuck. The inert gas is provided to the contact surface of the chuck and the back surface of the reticle via the plurality of openings in the chuck for releasing the reticle from the chuck.

The system and method of the present invention advantageously decrease the amount of time required to release the reticle from the electrostatic chuck in the EUV lithography system, thereby decreasing the time required for reticle changes during processing. This has the desirable effect of inreasing the throughput time of the EUV lithography system.

These and other advantages, aspects and novel features of the present invention, as well as details of an illustrated embodiment thereof, will be more fully understood from the following description and drawings.

### BRIEF DESCRIPTION OF SEVERAL VIEWS OF THE DRAWINGS

The accompanying drawings, which are incorporated herein and form a part of the specification, illustrate the present invention and, together with the description, further serve to explain the principles of the invention and to enable a person skilled in the pertinent art to make and use the invention.

FIG. 1 is a diagram of a prior art EUV lithography system.

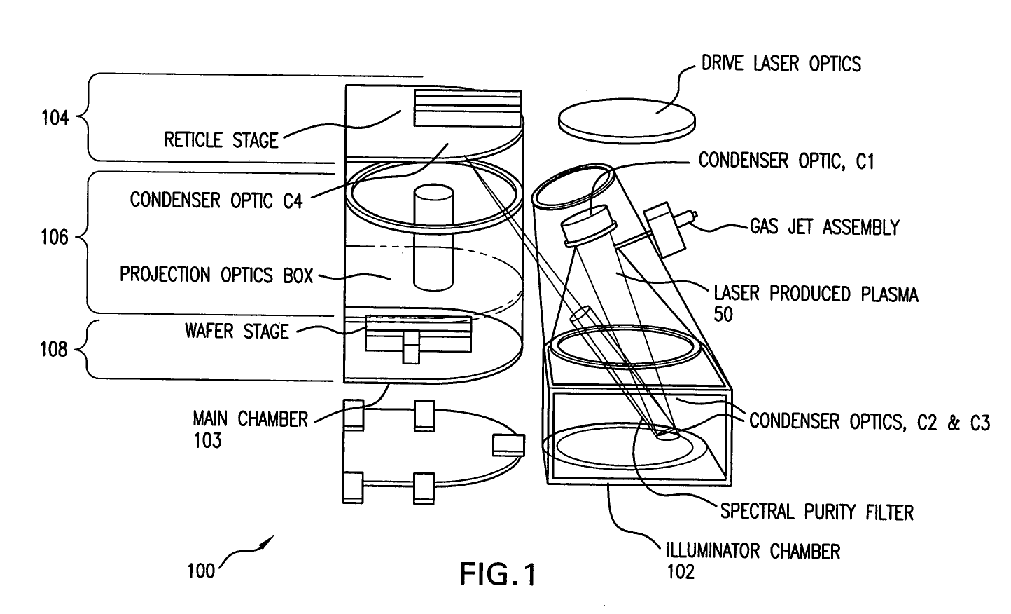

FIG. 2 is a simplified diagram of an EUV lithography system in accordance with one embodiment of the present invention.

FIG. 3 is simplified diagram of a reticle chuck for an EUV lithography system in accordance with another embodiment of the present invention.

### DETAILED DESCRIPTION OF THE INVENTION

The present invention will now be described in detail with reference to a few preferred embodiments thereof as illustrated in the accompanying drawings. In the following description, numerous specific details are set forth in order to provide a thorough understanding of the present invention. It will be apparent, however, to one skilled in the art, that the present invention may be practiced without some or all of these specific details. In other instances, well known process steps have not been described in detail in order not to unnecessarily obsure the present invention.

The invention generally pertains to an Extreme Ultraviolet (EUV) lithography system. More particularly, the invention pertains to an improved system and method for releasing a reticle from a reticle stage or chuck. One aspect of the invention relates to isolating the mask chamber, where the reticle and chuck are located, from the rest of the EUV lithography system and providing an inert gas, such as nitrogen, into the vacuum isolated mask chamber to assist in releasing the reticle from the chuck.

Another aspect of the invention relates to providing a chuck, mounted in the mask chamber, for directing the inert gas directly to the reticle. The chuck comprises a plurality of openings in the chuck connected to a gas supply line for providing the inert gas. The gas supply line provides the inert gas to the contact surface of the chuck and the back surface of the reticle via the plurality of openings in the chuck which assist in quickly releasing the reticle from the chuck.

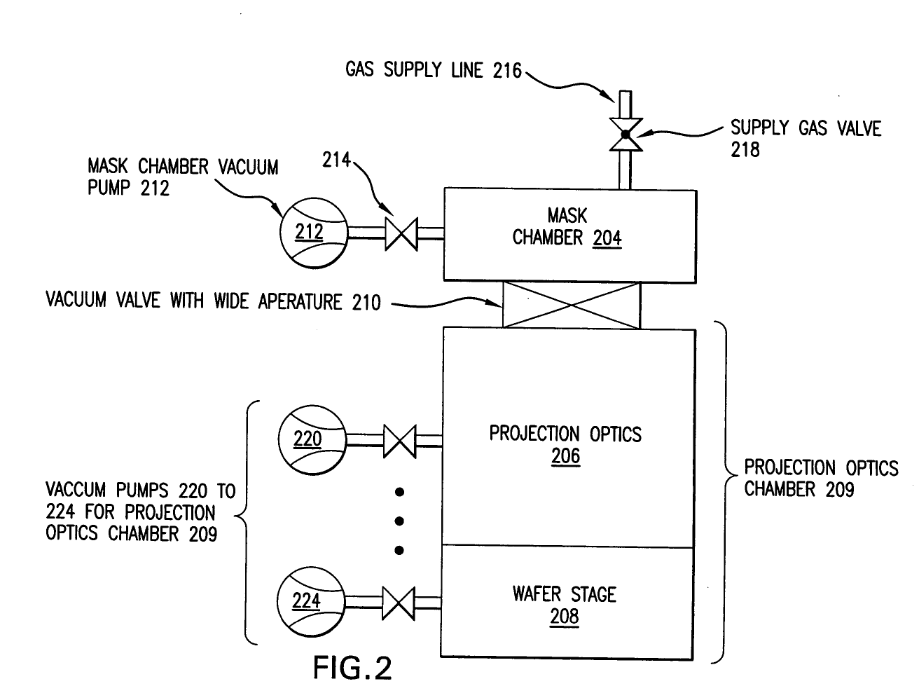

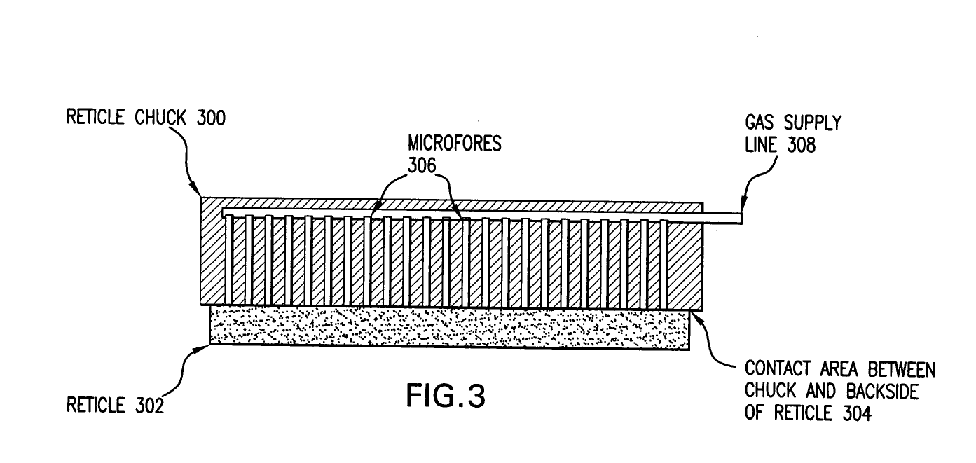

Embodiments of the invention are discussed below with references to FIGS. 2 and 3. However, those skilled in the art will readily appreciate that the detailed description given herein with respect to these figures is for explanatory purposes as the invention extends beyond these limited embodiments.

FIG. 2 is a simplified diagram of an EUV lithography system 200 in accordance with one embodiment of the present invention. The dimensions of various components are exaggerated to better illustrate the components of this embodiment. As shown, the EUV lithogaphy system 200 includes an illuminator chamber (not shown), a mask or reticle chamber 204 and a projection optics chamber 209 which containins the projection optics 206 and a wafer stage 208. Although not shown, the illuminator chamber houses a laser-produced or discharge-produced plasma source and the illumination system.

The mask chamber 204 is coupled to the projection optics chamber 209 via a vacuum valve 210. There may be one or more vacuum valves between the mask chamber 204 and the projection optics chamber 209. In a preferred embodiment, the vacuum valve 210 is a quickly closing and opening valve with a sufficiently wide aperture in order not to obstruct or restrict the optical path during EUV exposure of the wafer. In closed state, the one or more vacuum valves 210 isolate the mask chamber 204 from the projection optics chamber 209 such that no air or gas can leak from one chamber to the other. The present invention also includes a mask chamber vacuum pump 212 for quickly pumping down the mask chamber 204, a gas supply line 216 and two valves 214 and 218 for separating the mask chamber 204 from the vacuum pump 212 and from the gas supply line 216 respectively. Valves 210 and 214 are preferrably closed before the mask chamber is vented by opening valve 218 for dechucking the reticle. Then the gas supply line 216 supplies an inert gas, such as nitrogen, to the mask chamber 204. After reticle exchange, the mask chamber is re-evacuated by the vacuum pump 212, with valve 218 closed and valve 214 open. When the final pressure in the mask chamber is reached, valve 214 is reopened again during wafer processing. The present invention also includes at least one vacuum pump 220 for the projection optics chamber 209, comprising the projection optics 206 and the wafer stage 208. In a preferred embodiment, the projection optics 206 and the wafer stage 208 are in the same vacuum chamber, and the optical path between the two is unobstructed, as illustrated by the broken line in FIG. 2 which separates the projection optics 206 and the wafer stage 208. In another preferred embodiment, several separate vacuum pumps 220 to 224 are used to evacuate the projection optics chamber 209 such that a pressure gradient is generated to protect the projection optics from outgassing resist ingredients.

Thus, separating the mask chamber vacuum from the rest of the EUV lithography system enables the mask chamber to be flooded with an inert gas, such as nitrogen, without breaking the vacuum of the projection optics chamber. The gas molecules of the inert gas flood the mask chamber and flow over and around the reticle and the reticle chuck and reduce the adhesion forces between the extremely flat surfaces of the reticle and the chuck, thereby assisting in releasing the reticle from the reticle chuck. Thus, the present invention advantageously decreases the amount of time required to release the reticle from the chuck in the EUV lithography system, thereby decreasing the time required for reticle changes during processing. This in turn increases the throughput time of the EUV lithography system.

Referring now to FIG. 3, a reticle chuck 300 mounted in the mask chamber 204 for securley holding a reticle 302 in an EUV lithography system in accordance with one embodiment of the present invention is shown. In a preferred embodient, the reticle chuck 300 is an electrostatic chuck. The pressure of the contact area 304 between the reticle chuck 300 and the backside of the reticle 302 may have a pressure of up to 15 kPa under the conditions in an EUV lithography system. The reticle chuck 300 further includes a plurality of openings or micropores 306 in the reticle chuck 300 for supplying and distributing the inert gas to the contact area 304 between the reticle chuck 300 and the backside of the reticle 302. In one embodiment, a gas supply line 308 supplies the inert gas to the contact area 304 via the micropores 306. The gas supply line 308 may be a separate gas supply line leading to the reticle chuck 300 or may be the gas supply line 216 leading to the mask chamber 204 in FIG. 2. Thus, the reticle chuck 300 and the micropores 306 can supply the inert gas directly to the backside of the reticle 302 to quickly release the reticle 302 from the reticle chuck 300. Excess pressure may be used to separate the reticle from the chuck. Thus, the present invention advantageously decreases the amount of time required to release the reticle from the chuck in the EUV lithography system, thereby decreasing the time required for reticle changes during processing. This in turn increases the throughput time of the EUV lithography system.

While the invention has been described with reference to certain embodiments, it will be understood by those skilled in the art that various changes may be made and equivalents may be substituted without departing from the scope of the invention. In addition, many modifications may be made to adapt a particular situation or material to the teachings of the invention without departing from its scope. Therefore, it is intended that the invention not be limited to the particular embodiment disclosed, but that the invention will include all embodiments falling within the scope of the appended claims.

1. A lithography system for processing a substrate comprising:
a mask chamber having one or more vacuum valves for isolating the mask chamber from the rest of the lithography system;
a gas supply line adapted to provide an inert gas to the mask chamber; and
a vacuum pump adapted to evacuate the mask chamber.

2. The lithography system of claim 1 wherein the one or more vacuum valves are closed to isolate the mask chamber from the rest of the lithography system before venting the mask chamber with the inert gas provided by the gas supply line.

3. The lithography system of claim 1 wherein the inert gas is nitrogen.

4. The lithography system of claim 1 wherein the lithography system is an EUV system.

5. The lithogaphy system of claim 1 further comprising:
a chuck mounted in the mask chamber for holding a reticle, the chuck further comprising:
a contact surface for holding a back surface of the reticle to the chuck; and
a plurality of openings in the chuck, each opening having a first end and a second end, the first end of each opening being coupled to the gas supply line, and the second end of each opening being coupled to the contact surface of the chuck.

6. The lithography system of claim 5 wherein the gas supply line provides the inert gas to the contact surface of the chuck and the back surface of the reticle via the plurality of openings in the chuck, for releasing the reticle from the chuck.

7. The lithography system of claim 5 wherein the chuck is an electrostatic chuck.

8. A chuck for holding a reticle during processing, the chuck comprising:
a gas supply line adapted to provide an inert gas to the chuck;
a contact surface for holding a back surface of the reticle to the chuck; and
a plurality of openings in the chuck, each opening having a first end and a second end, the first end of each opening being coupled to the gas supply line, and the second end of each opening being coupled to the contact surface of the chuck.

9. The chuck of claim 8 wherein the gas supply line provides the inert gas to the contact surface of the chuck and the back surface of the reticle via the plurality of openings in the chuck, for releasing the reticle from the chuck.

10. The chuck of claim 8 wherein the inert gas is nitrogen.

11. The chuck of claim 8 wherein the chuck is mounted in an EUV system.

12. The chuck of claim 8 wherein the chuck is an electrostatic chuck.

13. A method for providing a vacuum isolated environment in a lithography system for dechucking a reticle, the method comprising the steps of:
providing a mask chamber having one or more vacuum valves for isolating the mask chamber from the lithography system;
closing the one or more vacuum valves to isolate the mask chamber from the rest of the lithogaphy system;
providing an inert gas to the mask chamber after the mask chamber has been isolated to dechuck the reticle.

14. The method of claim 13 wherein the inert gas is nitrogen.

15. The method of claim 13 wherein the lithography system is an EUV system.

16. The method of claim 13 further comprising the steps of:
providing a chuck mounted in the mask chamber for holding the reticle, the chuck having a contact surface for holding a back surface of the reticle to the chuck; and
providing a plurality of openings in the chuck, each opening having a first end and a second end, the first end of each opening being coupled to the gas supply line, and the second end of each opening being coupled to the contact surface of the chuck.

17. The method of claim 16 further comprising the step of:
providing an inert gas to the contact surface of the chuck and the back surface of the reticle via the plurality of openings in the chuck for releasing the reticle from the chuck.
